(19) United States
(12) Patent Application Publication
(10) Pub. No.: US 2011/0279287 A1
(43) Pub. Date: Nov. 17, 2011

(54) KEYBOARD WITH LASER POINTER AND MICRO-GYROSCOPE

(75) Inventor: YUNG-LUNG LIU, Ta Ya Shiang (TW)

(73) Assignee: Sunrex Technology Corp., Ta Ya Shiang (TW)

(21) Appl. No.: 12/778,491

(22) Filed: May 12, 2010

(51) Int. Cl. H03M 11/00

(52) U.S. Cl. 341/22

(57) ABSTRACT

A keyboard includes a laser pointer for generating laser radiation, and a micro-gyroscope for measuring a rotational angular speed or angular acceleration when the keyboard swings.

### BACKGROUND OF THE INVENTION

1. Field of Invention

The invention relates to computer input devices and more particularly to a keyboard having a laser pointer and a micro-gyroscope incorporated therein.

2. Description of Related Art

Keyboards are well known computer input devices. Keyboards are classified as wire and wireless keyboards. Some types of keyboard are equipped with track ball and/or touch panel, especially notebook computers. Still some types of keyboard are equipped with micro-projectors. A micro-projection installed in a keyboard of a computer can be used to project an image on a screen from the computer if there is no projector available at a meeting or briefing.

However, so far as the present inventor is aware, there are no prior documents about a keyboard equipped with a laser pointer commercially available. This can cause inconvenience if a person wants to point an important area on the screen if such need arises.

A gyroscope is a device for measuring or maintaining orientation, based on the principles of conservation of angular momentum. A mechanical gyroscope is essentially a spinning wheel or disk whose axle is free to take any orientation. This orientation changes much less in response to a given external torque than it would without the large angular momentum associated with the gyroscope's high rate of spin. Since external torque is minimized by mounting the device in gimbals, its orientation remains nearly fixed, regardless of any motion of the platform on which it is mounted. Applications of gyroscopes include navigation, stabilization of flying vehicles like radio-controlled helicopters, etc. Due to higher precision and the advancement of technology, a gyroscope is also mounted in mouses or global positioning system (GPS).

U.S. Pat. No. 6,901,799 discloses a vibratory double-axially sensing laser pointer which is characterized by including a base, a supporting hub on center of the base, a plurality suspending arms extended outwardly radially from the supporting hub, a platform at an outer end of the suspending arm, and a capacitance sensing electrode or a static-electricity driving electrode plated at each side of the platform top. A static-electricity driving electrode or a capacitance sensing electrode is arranged below the platform. When the gyroscope is rotated horizontally, the suspending arm and the platform will generate horizontal displacement caused by Coriolis force and, by measuring the change of capacitance value, the magnitude of the angular velocity of vibration is obtained.

However, so far as the present inventor is further aware, there are no prior documents about a keyboard equipped with a micro-gyroscope or a keyboard equipped with both laser pointer and micro-gyroscope commercially available. This can cause inconvenience in use if such need arises. Thus, the need for improvement still exists.

### SUMMARY OF THE INVENTION

It is therefore one object of the invention to provide a keyboard comprising a laser pointer for generating laser radiation; and a micro-gyroscope for measuring a rotational angular speed or angular acceleration when the keyboard swings.

In one aspect of the invention the laser pointer comprises a first switch mounted on the keyboard, a laser unit facing an aperture on the keyboard, a printed circuit board (PCB) behind the laser unit, and a rechargeable battery behind the PCB, the first switch, the laser unit, the PCB, and the rechargeable battery being electrically connected together.

In another aspect of the invention the micro-gyroscope comprises a second switch mounted on the keyboard, an annular base, a post on a center of the base, a plurality of equally spaced arms extending outward from the post, an outer end of each arm arcuately extending toward two opposite sides to form a horizontal arcuate platform with a gap being formed between any two adjacent platforms, a plurality of static-electricity driven electrodes each arranged between the corresponding platform and the base, and a plurality of sets of two capacitance sensing electrodes, the capacitance sensing electrodes of the same set being formed on tops of both ends of the platform, and wherein the capacitance sensing electrodes function as inertia weights of the micro-gyroscope.

The above and other objects, features and advantages of the invention will become apparent from the following detailed description taken with the accompanying drawings.

### BRIEF DESCRIPTION OF THE DRAWINGS

FIG. 1 is a perspective view of a keyboard having a laser pointer and a micro-gyroscope according to the invention;

FIG. 2 is an environmental view showing a first application of the keyboard (i.e., the activation of the micro-gyroscope) by cooperation with a projector which is electrically connected to a notebook computer;

FIG. 3 is an environmental view showing a second application of the keyboard (i.e., the activation of the laser pointer) by cooperation with the projector which is electrically connected to the notebook computer;

FIG. 4 is a schematic longitudinal sectional view of the laser pointer; and

FIG. 5 is a perspective view of the micro-gyroscope.

### DETAILED DESCRIPTION OF THE INVENTION

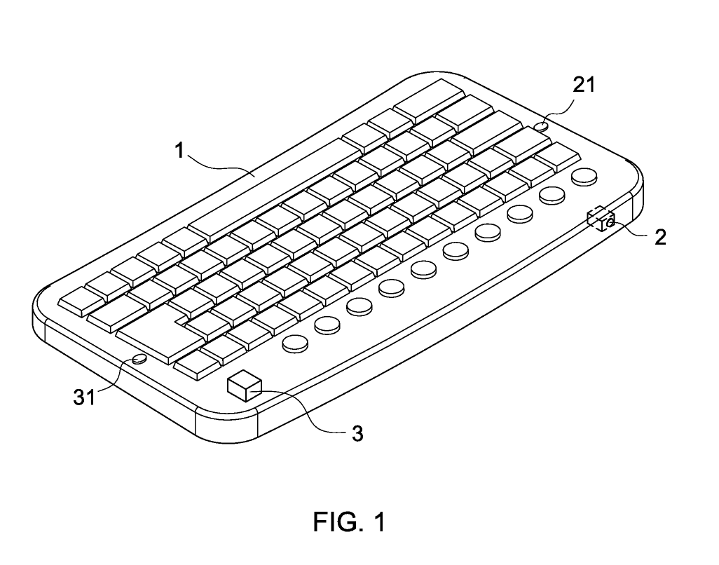

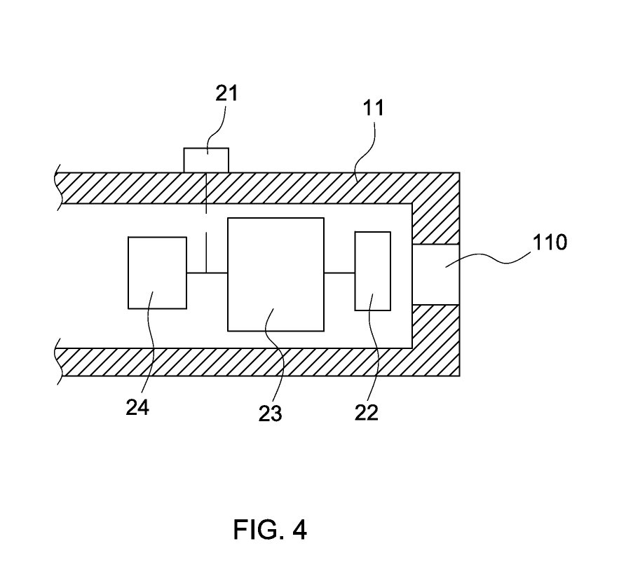

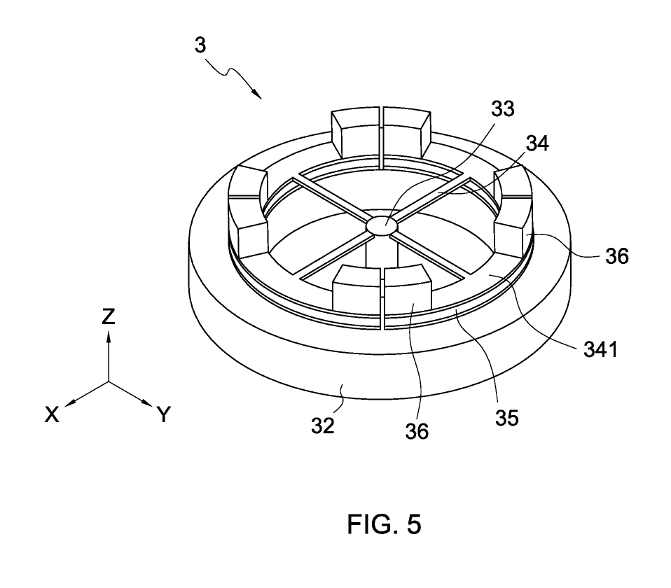

Referring to FIGS. 1 to 5, a keyboard 1 having a laser pointer 2 and a micro-gyroscope 3 in accordance with the invention is discussed in detail below.

The keyboard 1 has a housing 11 with the laser pointer 2 mounted on a position proximate to the left top corner thereof and the micro-gyroscope 3 mounted on a position proximate to the right top corner thereof. The keyboard 1 further has a first switch (e.g., push button switch) 21 on an intermediate portion of the left side, the first switch 21 being adapted to control on/off of the laser pointer 2, and a second switch (e.g., push button switch) 31 on an intermediate portion of the right side, the second switch 31 being adapted to control on/off of the micro-gyroscope 3.

The laser pointer 2 comprises a laser diode 22 facing an aperture 110 on a front edge of the housing 11, a printed circuit board (PCB) 23 in the rear of the laser diode 22, and a rechargeable battery 24 in the rear of the PCB 23. The above components are electrically connected together. Further, the first switch 21 is electrically interconnected the battery 24 and the PCB 23. The first switch 21 is normally open. A pressing of the first switch 21 will close same to supply power from the battery 24 to the laser diode 22 via the PCB 23. As a result, light is emitted by the laser diode 22.

The micro-gyroscope 3 is a vibratory gyroscope driven by both static-electricity and sensed capacitance. The micro-gyroscope 3 is mounted on an IC (integrated circuit) chip (not shown) and is electrically connected to the second switch 31. The micro-gyroscope 3 comprises an annular base 32, a post 33 on a center of the base 32, and a plurality of (e.g., four as shown) equally spaced arms 34 extending outward from the post 33. Preferably, the number of the arms 34 is a multiple of two. The outer end of each arm 34 arcuately extends toward two opposite sides so that four distinct horizontal arcuate platforms 341 are formed by the other ends of the arms 34. A gap is formed between any two adjacent platforms 341. That is, a discontinuous ring is formed by the platforms 341. The micro-gyroscope 3 further comprises four static-electricity driven electrodes 35 each arranged between the corresponding platform 341 and the base 32, and four sets of two metallic capacitance sensing electrodes 36 each having a predetermined height. The two metallic capacitance sensing electrodes 36 of the same set are formed on tops of both ends of the platform 341 by micro-electroplating. The capacitance sensing electrodes 36 function as inertia weights of the micro-gyroscope 3.

When the static-electricity driving electrodes 35 are electrically energized, the arms 34 and the platforms 341 are attracted each other by static-electricity to vibrate in Z direction. Further, a vibration phase difference between the arm 34 and its platform 341 of each set is 180 degrees. When the micro-gyroscope 3 rotates in X direction (or Y direction), the arm 34 and its platform 341 of each set displace a predetermine distance in X direction (or Y direction) due to Coriolis force. The capacitance sensing electrodes 36 will generate different capacitance values because the gap between two adjacent electrodes 36 of different sets is changed. Thus, the value of the rotational angular speed of the micro-gyroscope 3 can be obtained by measuring the difference of the measured capacitance values.

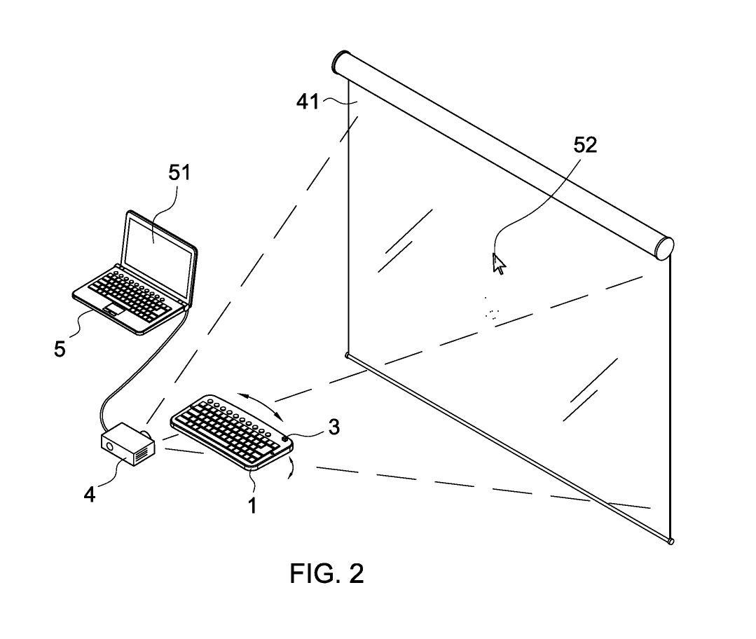

Referring to FIG. 2 specifically, a first application of the keyboard 1 (i.e., the activation of the micro-gyroscope 3) by cooperation with a projector 4 which is electrically connected to a notebook computer 5 is illustrated. The projector 4 may project an image on a screen 41 hanged on the wall from a display 51 of the notebook compute 5. A cursor 52 is shown on the screen 41. For moving the cursor 52, a person may press the second switch 31 and then swing the keyboard 1 to left of right as indicated by two-head arrow. The micro-gyroscope 3 is activated to measure a rotational angular speed or angular acceleration of the keyboard 1. As a result, the cursor 52 moves toward the desired position on the screen 41 to make an item on the position to be pointed.

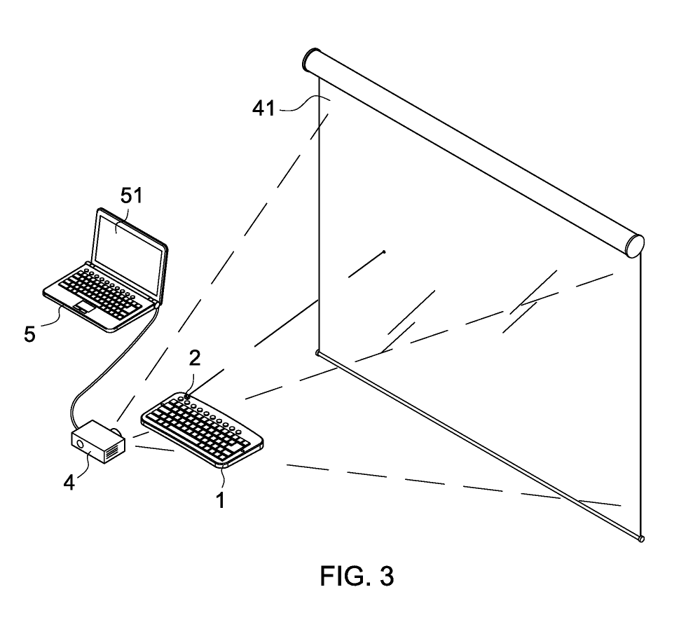

Referring to FIG. 3 specifically, a second application of the keyboard 1 (i.e., the activation of the laser pointer 2) by cooperation with the projector 4 which is electrically connected to the notebook computer 5 is illustrated. The projector 4 may project an image on the screen 41 hanged on the wall from the display 51 of the notebook compute 5. For making an item shown on the screen 41 prominent, a person may press the first switch 21 to activate the laser diode 22 to generate laser radiation to highlight something of interest on the screen 41.

Both of the first and second applications are particularly useful in briefing or meeting.

Preferably, the keyboard of the invention and the computer (e.g., notebook computer) can be constructed as a unit for component simplification, saving space, decreasing the manufacturing cost, and facilitating operation.

While the invention herein disclosed has been described by means of specific embodiments, numerous modifications and variations could be made thereto by those skilled in the art without departing from the scope and spirit of the invention set forth in the claims.

What is claimed is:

1. A keyboard comprising:
a laser pointer for generating laser radiation; and
a micro-gyroscope for measuring a rotational angular speed or angular acceleration when the keyboard swings.

2. The keyboard of claim 1, wherein the laser pointer comprises a first switch mounted on the keyboard, a laser unit facing an aperture on the keyboard, a printed circuit board (PCB) behind the laser unit, and a rechargeable battery behind the PCB, the first switch, the laser unit, the PCB, and the rechargeable battery being electrically connected together.

3. The keyboard of claim 2, wherein the laser unit is a laser diode.

4. The keyboard of claim 2, wherein the first switch controls on and off between the rechargeable battery and the PCB so that a pressing of the first switch supplies power from the rechargeable battery to the laser unit via the PCB for generating laser radiation.

5. The keyboard of claim 1, wherein the micro-gyroscope comprises a second switch mounted on the keyboard, an annular base, a post on a center of the base, a plurality of equally spaced arms extending outward from the post, an outer end of each arm arcuately extending toward two opposite sides to form a horizontal arcuate platform with a gap being formed between any two adjacent platforms, a plurality of static-electricity driven electrodes each arranged between the corresponding platform and the base, and a plurality of sets of two capacitance sensing electrodes, the capacitance sensing electrodes of the same set being formed on tops of both ends of the platform, and wherein the capacitance sensing electrodes function as inertia weights of the micro-gyroscope.

6. The keyboard of claim 5, wherein when the static-electricity driving electrodes are electrically energized, each of the arms and its platform are attracted each other by static-electricity to vibrate in Z direction, a vibration phase difference between the arm and its platform is 180 degrees, when the micro-gyroscope rotates in X direction or Y direction, the arm and its platform displace a predetermine distance in X direction or Y direction due to Coriolis force, the capacitance sensing electrodes generate different capacitance values because the gap changes, and the rotational angular speed or angular acceleration of the micro-gyroscope is obtained by measuring a difference between the capacitance values.

7. The keyboard of claim 5, wherein the number of the arms is a multiple of two.

8. The keyboard of claim 5, wherein the capacitance sensing electrodes are formed of metal.
